(19) United States
(12) Patent Application Publication
(10) Pub. No.: US 2025/0176103 A1
(43) Pub. Date: May 29, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Sanghyeok Kim, Suwon-si (KR); Sanghyun Han, Suwon-si (KR); Taehong Min, Suwon-si (KR); Sanghoon Kim, Suwon-si (KR)

(73) Assignee: SAMSUNG ELECTRO-MECHANICS CO., LTD., Suwon-si (KR)

(21) Appl. No.: 18/883,680

(22) Filed: Sep. 12, 2024

(30) Foreign Application Priority Data
Nov. 29, 2023 (KR) 10-2023-0169734

(51) Int. Cl. H05K 1/11; H05K 3/10

(52) U.S. Cl. CPC H05K 1/111; H05K 3/107; H05K 2201/09381; H05K 2201/09472; H05K 2201/099

(57) ABSTRACT

A printed circuit board includes a first insulating layer; a pad portion located on the first insulating layer; a connection layer located on the pad portion and including a central portion and an extension portion extending from the central portion toward an edge of the pad portion; and a second insulating layer located on a portion of the pad portion and a portion of the connection layer, in which the extension portion of the connection layer may be located within a groove portion formed in the second insulating layer, and an upper surface of the extension portion of the connection layer may be covered with the second insulating layer.

### CROSS-REFERENCE TO RELATED APPLICATION

This application claims priority to and the benefit of Korean Patent Application No. 10-2023-0169734 filed in the Korean Intellectual Property Office on Nov. 29, 2023, the entire contents of which are incorporated herein by reference.

### BACKGROUND

### 1. Field

The present disclosure relates to a printed circuit board and a manufacturing method thereof.

### 2. Description of the Related Art

As electronic devices in the IT field, including mobile phones, become smaller, and a size of metal posts formed on a printed circuit board on which electronic components are mounted is also becoming smaller.

As the size of the metal posts on the printed circuit board decreases, the metal posts may become separated from the printed circuit board and disappear.

### SUMMARY

The present disclosure attempts to provide a printed circuit board and a manufacturing method thereof capable of preventing a pad portion from being separated from the printed circuit board and lost.

However, problems to be solved by the present embodiments are not limited to the above-described problems and may be variously extended in the range of technical ideas included in the present embodiments.

According to some embodiments, a printed circuit board may include a first insulating layer; a pad portion located on the first insulating layer; a connection layer located on the pad portion and including a central portion and an extension portion extending from the central portion toward an edge of the pad portion; and a second insulating layer located on a portion of the pad portion and a portion of the connection layer, in which the extension portion of the connection layer may be located within a groove portion formed in the second insulating layer, and an upper surface of the extension portion of the connection layer may be covered with the second insulating layer.

The groove portion may be located on a lower surface of the second insulating layer.

A lower surface of the extension portion of the connection layer may be in contact with the pad portion.

The central portion of the connection layer may protrude above the second insulating layer.

The connection layer may further include a convex portion extending downward from the central portion and the extension portion.

The pad portion may include a concave portion formed on an upper surface of the pad portion.

The convex portion of the connection layer may be located within the concave portion of the pad portion.

The convex portion of the connection layer may be in contact with the pad portion.

According to some embodiments, a manufacturing method of a printed circuit board may include forming a pad portion on a first insulating layer; stacking a photosensitive film on the pad portion; forming a hole in the photosensitive film; forming a groove portion extending from the hole in the photosensitive film; and depositing a metal layer in the hole and the groove portion to form a connection layer including a central portion located in the hole and an extension portion located in the groove portion.

The manufacturing method may further include removing the photosensitive film; and stacking a second insulating layer on the pad portion and the connection layer.

The manufacturing method may further include removing a portion of the second insulating layer so that the central portion of the connection layer protrudes above the second insulating layer.

The groove portion may be formed on a lower surface of the photosensitive film.

A lower surface of the extension portion of the connection layer may be formed on the pad portion to be in contact with the pad portion.

The manufacturing method may further include removing a portion of an upper surface of the pad portion overlapping the hole of the photosensitive film to form a concave portion in the upper surface of the pad portion.

The forming of the connection layer may further include forming a convex portion extending downward from the central portion and the extension portion.

The convex portion of the connection layer may be formed within the concave portion of the pad portion.

The convex portion of the connection layer may be formed on the pad portion to be in contact with the pad portion.

According to the present embodiments, it is possible to provide a printed circuit board and a manufacturing method thereof capable of preventing a pad portion from being separated from the printed circuit board and lost.

However, it is obvious that the effects of the present embodiments are not limited to the above-described effects, and may be variously extended without departing from the spirit and scope of the present disclosure.

### BRIEF DESCRIPTION OF THE DRAWINGS

FIG. 1 is a schematic cross-sectional view of a printed circuit board according to an embodiment.

FIGS. 2 to 5 are schematic cross-sectional views illustrating a manufacturing method of a printed circuit board according to an embodiment.

FIG. 6 is a schematic cross-sectional view of a printed circuit board according to another embodiment.

FIGS. 7 to 10 are schematic cross-sectional views illustrating a manufacturing method of a printed circuit board according to another embodiment.

### DETAILED DESCRIPTION OF THE PRESENT EMBODIMENTS

Hereinafter, some embodiments of the present disclosure will be described in detail with reference to the accompanying drawings so that those skilled in the art to which the present disclosure pertains may easily practice the present disclosure. However, the present disclosure may be implemented in various different forms and is not limited to embodiments provided herein.

Portions unrelated to the description will be omitted in order to obviously describe the present disclosure, and similar components will be denoted by the same reference numerals throughout the present specification.

Further, it should be understood that the accompanying drawings are provided only in order to allow embodiments of the present disclosure to be easily understood, and the spirit of the present disclosure is not limited by the accompanying drawings, but includes all the modifications, equivalents, and substitutions included in the spirit and the scope of the present disclosure.

In addition, the size and thickness of each component illustrated in the drawings are arbitrarily indicated for convenience of description, and the present disclosure is not necessarily limited to the illustrated those. In the drawings, the thickness of layers, films, panels, regions, etc., are exaggerated for clarity. In addition, in the accompanying drawings, thicknesses of some of layers and regions have been exaggerated for convenience of explanation.

In addition, it will be understood that when an element such as a layer, a film, a region, or a plate is referred to as being “on” another element, it can be directly on the other element or intervening elements may also be present. In contrast, when an element is referred to as being “directly on” another element, there are no intervening elements present. In addition, when an element is referred to as being “on” a reference element, it can be positioned on or beneath the reference element, and is not necessarily positioned on the reference element in an opposite direction to gravity.

In addition, unless explicitly described to the contrary, the word “comprise,” and variations such as “comprises” or “comprising”, will be understood to imply the inclusion of stated elements but not the exclusion of any other elements.

Further, throughout the specification, the word “plan view” refers to a view when a target is viewed from the top, and the word “cross-sectional view” refers to a view when a cross section of a target taken along a vertical direction is viewed from the side.

Also, throughout the specification, when it is said to be “connected,” this does not mean that two or more components are directly connected, but means that two or more components are indirectly connected through another component, that two or more components are physically connected as well as electrically connected, or that two or more components are referred to by different names depending on their location or function, but are integral.

Hereinafter, various embodiments and modifications will be described in detail with reference to the drawings.

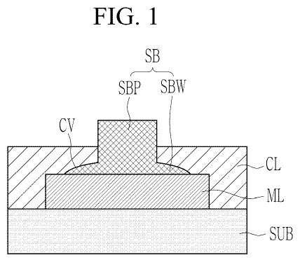

A printed circuit board according to some embodiments will be described with reference to FIG. 1. FIG. 1 is a schematic cross-sectional view of a printed circuit board according to some embodiments of the present disclosure.

Referring to FIG. 1, the printed circuit board according to the present embodiment may include a first insulating layer SUB, a pad portion ML located on the first insulating layer SUB, a connection layer SB located on the pad portion ML, and a second insulating layer CL disposing on the first insulating layer SUB and covering an exposed portion of the pad portion ML and a portion of the connection layer SB.

The second insulating layer CL may have a groove portion CV, which is a space formed between the second insulating layer CL and the pat portion ML, located on the pad portion ML. The groove portion CV may be formed on a lower surface of the second insulating layer CL, and may extend toward an edge of the pad portion ML.

The second insulating layer CL may include solder resist, but the present embodiment is not limited thereto.

The connection layer SB may include a central portion SBP protruding above the second insulating layer CL and an extension portion SBW extending laterally from the central portion SBP.

The central portion SBP of the connection layer SB may have a pillar shape, protrude upward from the surface of the second insulating layer CL, and be connected to an external device.

The connection layer SB may be in contact with the pad portion ML to electrically connect the printed circuit board to an external device.

The extension portion SBW of the connection layer SB may extend laterally from a lower portion of the central portion SBP and may be fill within the groove portion CV. An upper surface of the extension portion SBW of the connection layer SB may be covered with the second insulating layer CL, and a lower surface of the extension portion SBW of the connection layer SB may be in contact with the pad portion ML.

Although not illustrated, the pad portion ML may be connected to an additional wiring layer, which is located below the first insulating layer SUB or buried in the first insulating layer SUB, through a via formed in the first insulating layer SUB.

The printed circuit board may be connected to an external device through the connection layer SB including the central portion SBP protruding above the second insulating layer CL. Accordingly, the printed circuit board may be connected to an external element with a narrower cross-sectional area of the central portion SBP of the connection layer SB than the cross-section area of the pad portion ML.

According to the present embodiment, the extension portion SBW of the connection layer SB may be located in the groove portion CV formed between the second insulating layer CL and the pat portion ML, so that the extension portion SBW of the connection layer SB may be covered with the second insulating layer CL. Therefore, compared to the case where the connection layer SB does not include the extension portion SBW and is composed only of the central portion SBP, it is possible to prevent the connection layer SB from being lost from the printed circuit board due to external force or load applied from the outside, such as when the connection layer SB is in contact with an external device.

According to some embodiments, the lower surface of the extension portion SBW of the connection layer SB may be in contact with the pad portion ML, and thus, compared to the structure in which the connecting layer SB does not include the extension portion SBW and is composed only of the central portion SBP, a contact area between the connecting layer SB and the pad portion ML may be relatively wide. Therefore, by reducing a shear stress between the pad portion ML and the connection layer SB, it is possible to increase adhesion between the pad portion ML and the connection layer SB, and by reducing a contact resistance between the pad portion ML and the connection layer SB, it is possible to reduce a loss of electrical signals and reduce electrical resistance.

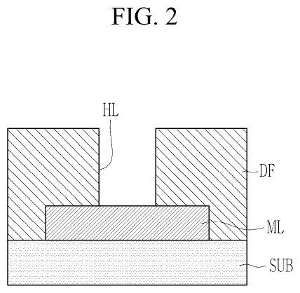

A manufacturing method of a printed circuit board according to some embodiments will be described with reference to FIGS. 2 to 5 along with FIG. 1. FIGS. 2 to 5 are schematic cross-sectional views illustrating a manufacturing method of a printed circuit board according to some embodiments.

Referring to FIG. 2, a pad portion ML may be formed on the first insulating layer SUB, a photosensitive film DF may be stacked on the pad portion ML, and a hole HL of the photosensitive film DF overlapping the pad portion ML may be formed.

The hole HL of the photosensitive film DF may be formed in a portion where the pillar-shaped central portion SBP of the connection layer SB is to be formed.

The photosensitive film DF may have photosensitivity and may be a dry film, but the present embodiment is not limited thereto.

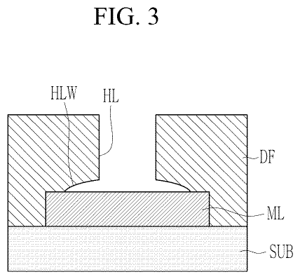

Referring to FIG. 3, an extended hole HLW extending toward the edge of the pad portion ML may be formed on a lower surface of the hole HL of the photosensitive film DF. The extended hole HLW of the photosensitive film DF may be formed by etching a portion of a lower surface of the photosensitive film DF by controlling etching conditions. The extended hole HLW of the photosensitive film DF may correspond to the groove portion CV of the second insulating layer CL.

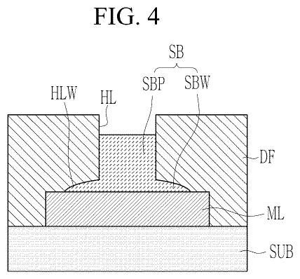

Referring to FIG. 4, a metal layer may be formed in the hole HL and the extended hole HLW of the photosensitive film DF, and the central portion SBP of the connection layer SB located in the hole HL of the photosensitive film DF and the extension portion SBW of the connection layer SB located in the extended hole HLW may be formed. The metal layer may be formed in a manner such as electrolytic plating, but the present embodiment is not limited thereto.

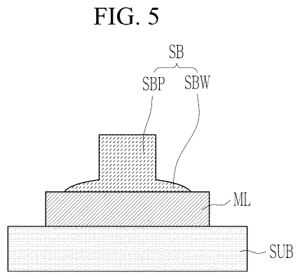

Referring to FIG. 5, the photosensitive film DF may be removed.

Thereafter, the printed circuit board illustrated in FIG. 1 may be formed by stacking the second insulating layer CL and lowering a height of the second insulating layer CL to expose the central portion SBP of the connection layer SB.

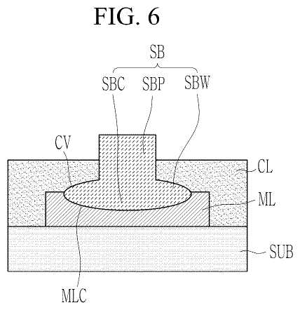

A printed circuit board according to another embodiment will be described with reference to FIG. 6. FIG. 6 is a schematic cross-sectional view of a printed circuit board according to another embodiment.

Referring to FIG. 6, the printed circuit board according to the present embodiment is similar to the printed circuit board according to the present embodiment previously described with reference to FIG. 1. Detailed descriptions of the same components may be omitted.

Referring to FIG. 6, the printed circuit board according to the present embodiment may include a first insulating layer SUB, a pad portion ML located on the first insulating layer SUB, a connection layer SB located on the pad portion ML, and a second insulating layer CL covering an exposed portion of the pad portion ML and a portion of the connection layer SB.

A groove portion CV that is located on the pad portion ML and extends toward an edge of the pad portion ML may be formed on a lower surface of the second insulating layer CL.

The connection layer SB may include a central portion SBP protruding above the second insulating layer CL and an extension portion SBW extending laterally from the bottom of the central portion SBP.

Unlike the printed circuit board according to the present embodiment of FIG. 1, the printed circuit board according to the present embodiment illustrated in FIG. 6 may include a concave portion MLC formed on an upper surface of the pad portion ML, and the connection layer SB may further include a convex portion SBC located within the concave portion MLC of the pad portion ML.

The central portion SBP of the connection layer SB may have a pillar shape, protrude upward from the surface of the second insulating layer CL, and be connected to an external device.

The extension portion SBW of the connection layer SB may extend laterally from a lower portion of the central portion SBP and may be located within the groove portion CV of the second insulating layer CL.

The convex portion SBC of the connection layer SB may extend into the concave portion MLC of the pad portion ML downward from a lower portion of the extension portion SBW and the central portion SBP of the connection layer SB.

The printed circuit board may be connected to an external device through the connection layer SB including the central portion SBP protruding above the second insulating layer CL. Accordingly, the printed circuit board may be connected to an external element with a narrower cross-sectional area than the pad portion ML.

According to the present embodiment, the extension portion SBW of the connection layer SB may be located in the groove portion CV formed inside the second insulating layer CL, and thus the extension portion SBW of the connection layer SB may be covered with the second insulating layer CL. Therefore, compared to the structure in which the connection layer SB does not include the extension portion SBW and is composed only of the central portion SBP, it is possible to prevent the connection layer SB from being lost from the printed circuit board due to external force or load applied from the outside, such as when the connection layer SB is in contact with an external device.

According to the present embodiment, the convex portion SBC of the connection layer SB extending from the lower portion of the extension portion SBW and the central portion SBP of the connection layer SB are located within the concave portion MLC of the pad portion ML, and thus a contact area between the connection layer SB and the pad portion ML may be relatively wide. Therefore, by reducing a shear stress between the pad portion ML and the connection layer SB, it is possible to increase adhesion between the pad portion ML and the connection layer SB, and by reducing a contact resistance between the pad portion ML and the connection layer SB, it is possible to reduce a loss of electrical signals and reduce electrical resistance.

Many features of the printed circuit board according to the present embodiment previously described with reference to FIG. 1 are all applicable to the printed circuit board according to the present embodiment.

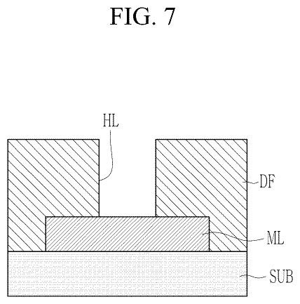

A manufacturing method of a printed circuit board according to some embodiments will be described with reference to FIGS. 7 to 10 along with FIG. 6. FIGS. 7 to 10 are schematic cross-sectional views illustrating a manufacturing method of a printed circuit board according to another embodiment.

Referring to FIG. 7, a pad portion ML may be formed on the first insulating layer SUB, a photosensitive film DF may be stacked on the pad portion ML, and a hole HL overlapping the pad portion ML may be formed.

The hole HL of the photosensitive film DF may be formed in a portion where a pillar-shaped central portion SBP of a connection layer SB is to be formed.

The photosensitive film DF may have photosensitivity and may be a dry film, but the present embodiment is not limited thereto.

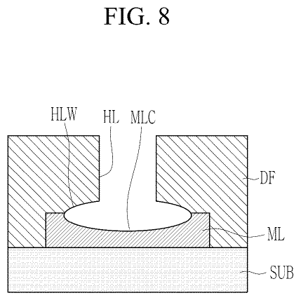

Referring to FIG. 8, an extended hole HLW extending toward an edge of the pad portion ML may be formed on a lower surface of the hole HL of the photosensitive film DF, and a concave portion MLC of the pad portion ML may be formed by etching a portion of the upper surface of the pad portion ML. The extended hole HLW of the photosensitive film DF may be formed by etching a portion of the lower surface of the photosensitive film DF by controlling etching conditions, and the concave portion MLC of the pad portion ML may be formed by etching the upper surface of the pad portion ML exposed by the hole HL and the extended hole HLW of the photosensitive film DF by controlling the etching conditions.

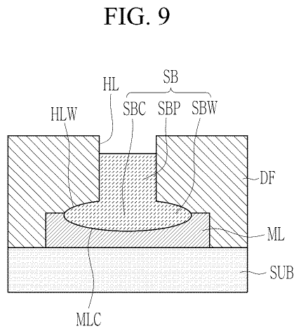

Referring to FIG. 9, a metal layer is formed within the hole HL and the extended hole HLW of the photosensitive film DF, and the concave portion MLC of the pad portion ML, so the central portion SBP of the connection layer SB located within the hole HL of the photosensitive film DF, the extension portion SBW of the connection layer SB located within the extended hole HLW, and the convex portion SBC of the connection layer SB located within the concave portion MLC of the pad portion ML are formed.

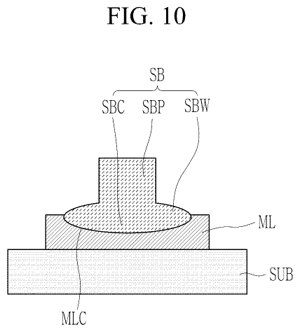

Referring to FIG. 10, the photosensitive film DF may be etched to be removed. Thereafter, the printed circuit board illustrated in FIG. 6 may be formed by stacking the second insulating layer CL and lowering a height of the second insulating layer CL to expose the central portion SBP of the connection layer SB.

Many features of the manufacturing method of a printed circuit board according to the present embodiment previously described with reference to FIGS. 2 to 5 are all applicable to the manufacturing method of a printed circuit board according to the present embodiment.

Although preferred embodiments of the present disclosure have been described above, the present disclosure is not limited thereto, and the present disclosure can be variously modified within the scope of the claims, the detailed description of the disclosure, and the appended drawings, and it is natural that various modifications also fall within the scope of the present disclosure.

### DESCRIPTION OF SYMBOLS

ML: Pad portion
MLC: Concave portion
SB: Connection layer
SBP: Central portion
SBW: Extension portion
SBC: Convex portion
SUB, CL: Insulating layer
CV: Groove portion

What is claimed is:

1. A printed circuit board, comprising:
a first insulating layer;
a pad portion located on the first insulating layer;
a connection layer located on the pad portion and including a central portion and an extension portion extending from a bottom of the central portion toward a top surface edge of the pad portion; and
a second insulating layer disposed on the first insulating layer and covering an exposed portion of the pad portion and a portion of the connection layer,
wherein the extension portion of the connection layer is located within a groove portion which is a space formed between the second insulating layer and the pad portion, and an upper surface of the extension portion of the connection layer is covered with the second insulating layer.

2. The printed circuit board of claim 1, wherein
the groove portion is located on a lower surface of the second insulating layer and on a top of the pad portion.

3. The printed circuit board of claim 2, wherein:
a lower surface of the extension portion of the connection layer is in contact with the pad portion.

4. The printed circuit board of claim 3, wherein
the central portion of the connection layer protrudes above the second insulating layer.

5. The printed circuit board of claim 2, wherein
the connection layer further includes a convex portion extending downward from the central portion and the extension portion.

6. The printed circuit board of claim 5, wherein
the pad portion includes a concave portion in an upper surface of the pad portion.

7. The printed circuit board of claim 6, wherein
the convex portion of the connection layer is located within the concave portion of the pad portion.

8. The printed circuit board of claim 7, wherein
the convex portion of the connection layer is in contact with the pad portion.

9. The printed circuit board of claim 8, wherein
the central portion of the connection layer protrudes above the second insulating layer.

10. The printed circuit board of claim 1, wherein
the central portion of the connection layer protrudes above the second insulating layer.

11. A manufacturing method of a printed circuit board, comprising:
forming a pad portion on a first insulating layer;
stacking a photosensitive film on the pad portion and the first insulating layer;
forming a hole in the photosensitive film;
forming a groove portion extending from a bottom of the hole in the photosensitive film; and
depositing a metal layer in the hole and the groove portion to form a connection layer including a central portion located in the hole and an extension portion located in the groove portion.

12. The manufacturing method of claim 11, further comprising:
removing the photosensitive film; and
stacking a second insulating layer on the pad portion, the connection layer, and the first insulating layer.

13. The manufacturing method of claim 12, further comprising:
removing a portion of the second insulating layer such that the central portion of the connection layer protrudes above the second insulating layer.

14. The manufacturing method of claim 11, wherein
the groove portion is formed on a lower surface of the photosensitive film.

15. The manufacturing method of claim 14, wherein:
a lower surface of the extension portion of the connection layer is formed on the pad portion to be in contact with the pad portion.

16. The manufacturing method of claim 11, further comprising:
removing a portion of an upper surface of the pad portion overlapping the hole of the photosensitive film to form a concave portion in the upper surface of the pad portion.

17. The manufacturing method of claim 16, wherein
the forming of the connection layer further includes forming a convex portion extending downward from the central portion and the extension portion.

18. The manufacturing method of claim 17, wherein
the convex portion of the connection layer is formed within the concave portion of the pad portion.

19. The manufacturing method of claim 18, wherein:
the convex portion of the connection layer is formed on the pad portion to be in contact with the pad portion.
